(19) United States
(12) Patent Application Publication
(10) Pub. No.: US 2019/0229225 A1
(43) Pub. Date: Jul. 25, 2019

(54) METHOD FOR THE ENCAPSULATION OF PHOTOVOLTAIC PANELS IN USING PRE-IMPREGNATED MATERIALS

(71) Applicant: Total Solar International, Courbevoie (FR)

(72) Inventor: Raphael Dinelli, Olonne-Sur-Mer (FR)

(21) Appl. No.: 16/336,781

(22) PCT Filed: Sep. 27, 2017
(86) PCT No.: PCT/FR2017/052616

§ 371 Date: Mar. 26, 2019

(30) Foreign Application Priority Data
Sep. 29, 2016 (FR) 1659368

(51) Int. Cl. H01L 31/048; H01L 31/049

(52) U.S. Cl. CPC H01L 31/0481; H01L 31/049

(57) ABSTRACT

A method for manufacturing a panel of photovoltaic cells includes baking a stack of a plurality of layers having different materials. The plurality of layers includes the following materials: a translucent front layer made of polymer, at least two layers of dry fabric made of fiberglass, at least two layers of fiberglass fabric pre-impregnated with epoxy resin, a layer of photovoltaic cells and a back layer made of polymer. The use of fiberglass fabrics impregnated with epoxy resin ensures excellent mechanical strength for the panel over time under the effect of climatic conditions. Prior to stacking the layers, the method includes making the layer of photovoltaic cells, including connecting rows of series-connected cells, the rows being connected to one another by field-effect transistors encapsulated in the panel at the end of the baking step.

### 1. FIELD OF THE INVENTION

The invention relates to a method for the manufacture of solar panels provided with a plurality of thin layers encapsulated in resin and the to panel obtained from this manufacturing method. The present invention relates more particularly to the fact that the method uses layers of polymers and a pre-impregnated fabric made of epoxy resin, placed on either side of the layer constituted by the photovoltaic cells.

### 2. TECHNOLOGICAL BACKGROUND

Owing to reduction of the reserves of fossil-fuel energies and the increase in pollution caused by the consumption of these materials, the use of natural resources and energy consumption is increasingly being governed by a logic of sustainable development. This trend is naturally leading to preferences for natural energies such as solar energy. It is now standard practice to install photovoltaic panels especially on roofs of companies, public buildings or simply the roofs of personal dwellings to provide energy to the devices and equipment of the dwelling in question or to retail this energy to a provider.

Solar panels must be thin and light enough to limit their weight and space requirement, making it possible for example to embed them in a vehicle. In order to adapt to very diverse locations and function under harsh climatic conditions, vibrations and mechanical stresses in general, the panels must possess a structure that is sufficiently resistant while being fine. To resolve these constraints of structure, there are known ways of encapsulating panels of photovoltaic cells in a coating material such as polymer and a glass plate to the detriment of the weight factor.

Photovoltaic cells must be protected both from the mechanical viewpoint and against external adverse factors such as air and water. In addition, the shape of the support may vary appreciably, and it may especially have a curved reception surface. It is therefore necessary to be able to adapt the shape of the photovoltaic panel to that of the support. In general, when designing and manufacturing an encapsulated photovoltaic panel, it is therefore sought to provide the encapsulated panel with all the following properties:
minimum thickness;
lightness;
deformability;
translucence;
hermetic sealing;
reliability.

The patent application FR2 934 418 filed by the present Applicant describes a method for encapsulating a panel of photovoltaic cells by a method for the injection/infusion of resin on fiber-glass fabrics. This document teaches a technique for encapsulating panels of photovoltaic cells that preserves the possibility of obtaining a deformable encapsulated panel. More specifically, the prior-art application cited here above comprises especially steps for applying several fiberglass fabrics in a mold and injecting a resin under infusion, said step of injection being accompanied by a step for degassing said resin, leading to the obtaining of an encapsulated panel.

Although it produced wholly encouraging results, this method as described has several drawbacks. The resin infusion method does not give a structural quality that is reliable over time with fine layers of materials. Indeed, the climatic conditions ultimately cause the materials to get detached by delamination. In addition, the epoxy resin yellows over time under the prolonged effect of sunlight and inclement weather and the panel suffers performance losses and no longer has a pleasant appearance. The implementation of the method for injecting epoxy resin is fairly complicated because it requires know-how and a great deal of time to be set up. Finally, the method generates substantial quantities of consumable materials that are lost, converted into waste, tubing, plastic film, etc.

In general, a solar panel is composed of photovoltaic cells mounted in series to augment the voltage of the module. Positive and negative connectors convey the current towards the regulation system. When the module is under shade or shadowed, the nominal voltage transmitted to the regulation collapses and causes the module to be shorted. The current produced by the unshadowed or unshaded cells passes through the shadowed cells and there is a risk that the latter will undergo excess voltage. To avert this phenomenon, the series-mounted cells are connected to diodes known as “bypass” cells which block the current to the shadowed cells. Since these diodes are bulky, they are installed in a junction box fixed to the surface of the panel. The presence of a multitude of junction boxes has numerous drawbacks when they are used on the front face of the panel. The presence of these junction boxes reduces the working surface area of the panel and therefore its overall efficiency. The connectors used to connect these diodes and the surface area of the junction box increase the surface area to the detriment of the working surface area of the cells. In addition, the diodes release heat when they work and necessitate a certain volume for the junction box. Finally, the ventilation needed is provided by an aperture that is not moisture-proof. Over time, the moisture corrodes the connectors and creates false contacts which may cause outbreaks of fire.

The invention is aimed especially at overcoming at least some of these drawbacks of the prior art. More specifically, a main object of the invention is to facilitate manufacture, provide adequate strength to materials and improve the reliability of the panels by limiting losses in efficiency due to ageing.

### 3. SUMMARY OF THE INVENTION

One particular embodiment of the invention proposes a method for manufacturing a panel of photovoltaic cells comprising a step for baking a stack of a plurality of layers comprising different materials. The plurality of layers comprises the following layers:
a translucent front layer made of polymer.
at least two layers of dry fabric made of fiberglass,
at least two layers of fiberglass fabric pre-impregnated with epoxy resin,
a layer of photovoltaic cells,
a back layer made of polymer.

The novel method corrects the defects of the first invention described in the patent application FR2 934 418. Indeed, the use of a epoxy-resin-impregnated fiberglass fabrics associated with polymer films ensures excellent mechanical strength for the panel over time and under the effect of climatic conditions. The polymer films used prevent the panel from yellowing under the influence of ultraviolet rays and/or temperature and/or moisture. In addition, the use of these materials allows industrial-scale materials as compared with the prior-art infusion approach. In addition, the use of these materials provides increased flexibility of the panel as well has high flexibility of use to enable the panels thus manufactured to be affixed to any type of support.

The module can be manufactured on a standard production line for solar panels in adapting it to the novel materials used and to the novel steps of the manufacturing process. These products are considered to be dry laminates that are laid successively on a surface plate or surface planished plate in order to build the module.

According to a first embodiment, the stacking consists in stacking the layers here below in the order given:
the translucent polymer layer placed on the front of the panel,
a layer of fiberglass dry fabric,
a layer of fiberglass fabric pre-impregnated with epoxy resin,
the layer of photovoltaic cells,
a second layer of fiberglass dry fabric,
a second layer of fiberglass fabric pre-impregnated with epoxy resin,
the polymer back layer of the panel.

In this way, the resin that pre-impregnates the fabrics spreads more efficiently in the stack and ensures more efficient fixed attachment between the layers after baking.

According to another embodiment, the translucent polymer layer that is first on the stack is in contact with a support such as an encapsulation surface plate on which the baking step is performed. In this way, the layer on the top of the panel, i.e. the layer imprinted by the encapsulation encapsulating surface plate has a smooth appearance without roughness.

According to another embodiment, the baking steps begins with a preliminary step of placing the stack under vacuum. This can be done for example by applying a vacuum-creating film on the stack and drawing out the air from beneath the film by means of a vacuum pump. In this way, the layers are held under pressure and immobile during the baking and the gases present before this step or generated during this step are easily discharged to the exterior of the stack.

According to another embodiment, the step for stacking layers consists of the application of the layers of dry fabric with dimensions greater than that of at least the layer of photovoltaic cells, the method furthermore comprises a finishing step consisting especially in trimming the panel thus made. In this way, the drawing out of the gases by the side of the stack is made easier and each encapsulated layer possesses the same dimension.

According to another embodiment, the baking step consists in maintaining a first temperature level for a determined duration and a second temperature level having a value greater than that of the first level for a second determined duration and keeping the stack without moving it after baking for a third determined duration. In this way, the polymerization of the epoxy resin that pre-impregnates the fabrics is carried out in an optimal manner

According to another embodiment, the baking of the stack under vacuum is done in a laminator. In this way, the baking can be automated.

According to another embodiment, prior to the step for stacking layers, the method comprises a step for making the layer of photovoltaic cells comprising the connection of rows of series-connected cells, for example, said rows being sometimes connected to one another by field-effect transistors that are encapsulated in the panel at the end of the baking step. In this way, the transistors are integrated into the stack thus preventing the use of junction boxes and the working surface area of the panels is thus increased.

According to another embodiment, the method of manufacture comprises a step for setting up connectors electrically connected to electrical bus lines connected to the cells and coming out of the stack, the connectors being capped by silicone-filled packages. In this way, the making of the panels is speedier and comprises fewer elements to be mounted

According to another aspect, the invention relates to a panel of photovoltaic cells comprising a layer of photovoltaic cells and being derived from the method of manufacture according to any one of the above paragraphs.

According to another aspect, the invention relates to a photovoltaic panel comprising at least one stack of layers in the following order:
the translucent polymer layer placed on the front of the panel,
a layer of fiberglass dry fabric and a layer of fiberglass fabric pre-impregnated with epoxy resin,
the layer of photovoltaic cells,
a second layer of fiberglass dry fabric and a second layer of fiberglass fabric pre-impregnated with epoxy resin,
the polymer back layer of the panel.

5

### 4. LIST OF FIGURES

Other features and advantages of the invention shall appear from the following description given by way of an indicative and non-exhaustive example, and from the appended drawings of which:

FIG. 1 presents a sequencing of the steps illustrating a method of encapsulation of photovoltaic cells, according to a preferred embodiment of the invention;

FIG. 2 shows a connection made on the prototype between two photovoltaic cells electrically connected by a MOSFET transistor;

FIG. 3 presents a side of a photovoltaic panel being manufactured according to one example of an embodiment;

FIG. 4 is an example of a diagram showing the succession of layers to be made before the baking step;

FIG. 5 illustrates the variation of temperature as a function of time for the baking of layers according to one example of an embodiment;

FIG. 6 shows a diagram of a lamination device enabling the baking and the pressurizing of the layers of materials, known as “laminate”.

### 5. DETAILED DESCRIPTION

In all the figures of the present document, the identical elements (or steps) are designated by a same numerical reference.

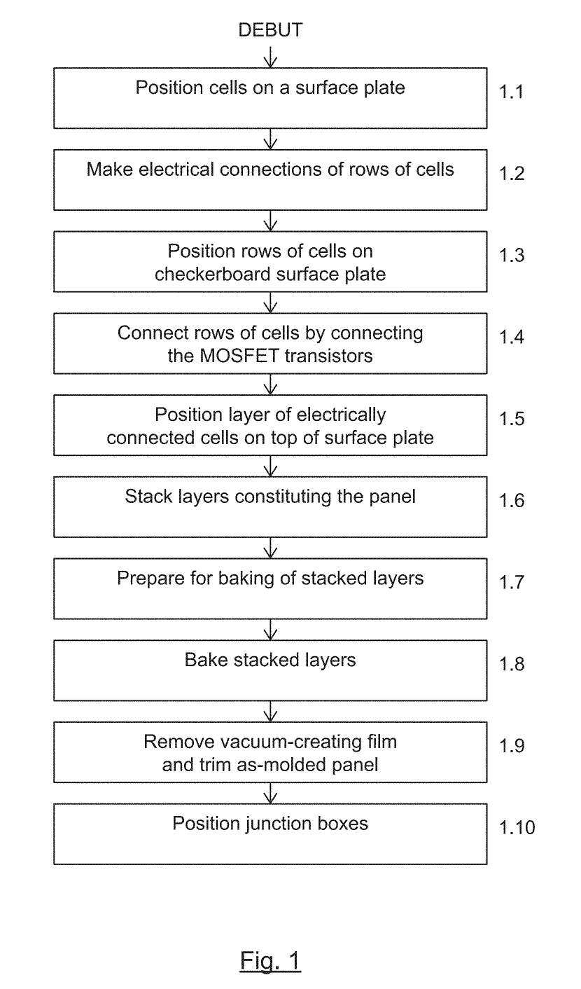

Referring now to FIG. 1, we present a sequencing of the steps illustrating a method of encapsulation of photovoltaic cells using composite and polymer materials, according to a preferred embodiment of the invention.

Solar panels comprise photovoltaic cells which need to be assembled and electrically connected to one another. These photovoltaic cells may be of the “front contact” type, meaning that the electrical connections are made on the front face (one polarity) and on the back face (the other polarity) of the cell or of the “back contact” type, meaning that the electrical connection is all made on the back face of the cell.

According to one preferred embodiment, the cell used is of the monocrystalline Sunpower type. The cell used may also be of the polycrystalline type. This cell, which is very efficient, is of the “back contact” type. Because of their fineness and great brittleness, photovoltaic cells should not be handled manually. Gripping tools have been developed to move the cells. They comprise suction cups. The cell is held at the end of the tools by an air vacuum made in the suction cup. In particular, there is a manual tool for the handling of a single cell, or a rack supporting a series of suction cups fixed in line or again a geometrical frame supporting suction cups forming a checkerboard. According to a first step 1.1, the cells are placed with the manual tool on a support such as a positioning surface plate made of aluminum and having dimensions of 1700 mm by 1000 mm for example. In the prototype made for the manufacture of panels, we use at least two models of positioning surface plates: an inline surface plate to linearly assemble a determined number of cells (6 for example) and a checkerboard surface plate to assemble an entire panel of cells (12 rows of 6 cells for example). Imprints or impressions on top of the surface plate coincide perfectly with the external dimensions of the cell, with a clearance of 0.2 mm in width and in length. Clearances are made in the machining profile of the surface plate to prevent the cell from breaking when it is being lifted by means of the gripping tool.

When the cells are placed on the inline surface plate in complying with their polarities, the electrical connections are made (step 1.2). Conductive strips called “tabs” are pre-tinplated and then positioned on the edge of the cells. Weights (or “ballasting ingots”) are used to hold the tabs and the cells. Through brazing at 380° C., the pre-tinning and the flux enable efficient moisturizing of the cell and of the tab by a tin-lead alloy. Other conductive strips, here below called “output strips” are assembled at the extremities. At the step 1.3, each row of electrically connected cells is shifted by means of a gripping tool and positioned on the checkerboard-shaped assembling surface plate. At this stage, it may be useful to verify the electrical conduction of the rows of cells. To this end, the cells are illuminated and an operator verifies the open-circuit voltage across the terminals of the cells at the extremities of the rows.

The rows of cells will now be electrically connected with one another through a “by-pass” type shunt components. In panels commercially available on the date of the filing of this patent, these components are simple diodes. These diodes have a security function and are used only in the event of partial shadowing of the panel. They then enable the current to be shunted and prevent the hotspot phenomenon. These diodes are generally placed in junction boxes which must then have a volume great enough to act as heat sinks. To reduce the amount of space taken up by the junction boxes, the method described in the present application plans for the use of insulated-gate field-effect transistors commonly known as a MOSFETS or metal oxide semi-conductor field-effect transistors. For made and tested prototypes, the SPV1001 component by ST MICROELECTRONICS (sized 5 mm×6 mm, with a thickness 0.9 mm) was used and then the SPV1520 component of the same structure. It goes without saying that these references are given only as examples. According to one alternative embodiment, the MOSFET transistors are replaced by standard diodes. By using such components, the dissipation is limited and enables direct encapsulation in the composite materials.

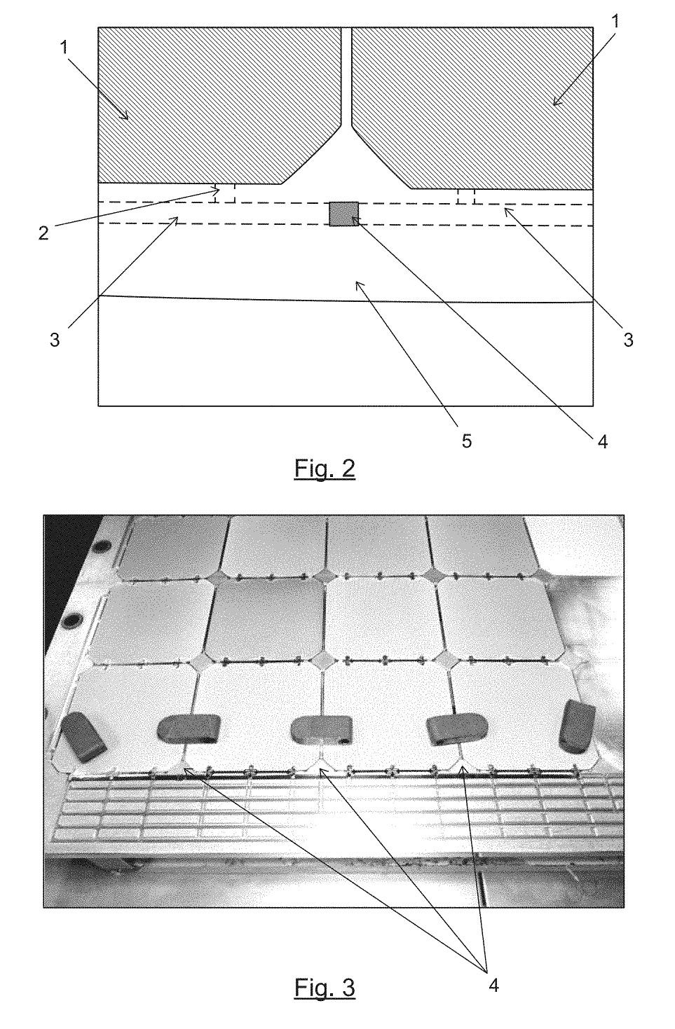

An output collector bus line constituted by a portion of copper ribbon is disposed along each cell terminating a row. The bus lines have approximately the same length as the cells, leaving between each line a space of 2 millimeters. At the step 1.4, an operator places a MOSFET transistor on this space and solders it to both extremities of the line facing each side of this space. FIG. 2 shows a connection made. The figure shows two photovoltaic cells 1, output strips 2 connecting the cells to the output bus line 3 and the MOSFET transistor 4 connecting the cells between the two lines. The operator takes special care to comply with the polarity of the component. In this figure, we can also see the surface plate 5 on which the cells are placed.

FIG. 3 presents one side of a panel being made, showing four rows, of which the cells at one extremity are connected by three strips to a collector bus line. MOSFET transistors 4 can be seen on the collector bus lines at the point of intersection with a straight line passing along the longitudinal sides of the rows of cells. Once the electrical circuit is made, the assembly of cells is surrounded at the top and at the bottom by protective layers. At the step 1.5, the layer formed by all the cells is moved on to the top of an encapsulation surface plate by means of the gripping tool formed by suction cups forming a checkerboard. This surface plate has been preliminarily coated with a layer of wax of the CIREX S1 042 type.

The method of manufacture comprises the application of layers made of composite materials and polymers according to a precise sequencing. The composite materials provide for the encapsulating of the cells and strips. They take the form of fiberglass fabrics that are impregnated with epoxy resin or are dry. Once the layers of fabric are connected homogenously and irreversibly by the reticulated resin, the photovoltaic cell is solidly trapped between two layers of composite materials, and the cell is then encapsulated.

Here are examples of layers Ci successively applied to the encapsulating surface plate during a step of stacking 1.6, and prior to the baking step:
C1: translucent layer on the front of the panel (known as a “frontsheet”), i.e. an upper surface film for tight sealing and protection against UV rays responsible for the yellowing of the epoxide resin. The reference film Tedlar Tut 10BG3 0.025 mm is used for the prototype. This front layer or frontsheet of the panel is preferably made of polymer and can be applied in solid form (a plastic film extending on the surface of the panel) or by using liquid means that solidify at the time of baking.
C2: this is a lay of dry fabric, made of fiberglass for example. The film referenced RE 70P model Plain EGL: 70 gr/m2, width 1000 mm, given by the firm Hexcel is used for the prototype.
C3: this is a fiberglass layer pre-impregnated with epoxy resin, typically 200 gr/m². The film reference is WT93/RE200P/1270/60%/S/S, is used for the prototype.
C4: this is the layer of a photovoltaic cells connected by strips and provided with MOSFET transistors. The cells are of the front contact type or of the back contact type. The present application concerns any type of photovoltaic cells producing electricity.
C5: this is again a layer of dry fabric made of fiberglass for example (RE 70P).
C6: this is again a layer of glass fabric pre-impregnated with epoxy resin, typically 200 gr/m², having the same reference: WT93/RE200P/1270/60%/S/S.
C7: this is the back layer or ‘backsheet’, it is a surface film enabling hermetic sealing and serving as a UV barrier, made of polymer, preferably opaque polymer but it can also be translucent. The film referenced TPM 125 BLANC BTPMWH0262RDER, white in color, is used for the prototype. This back layer or backsheet of the panel is preferably made of polymer and can be applied in solid form (a plastic film extending on the surface of the panel) or by liquid means that solidify at the time of baking in preserving elastic properties.

According to a preferred embodiment, the layer of dry fabric and the layer of fabric pre-impregnated with resin are situated on each side of the layer of photovoltaic cells. According to a simplified embodiment, the layers of dry fabric and of fabric pre-impregnated with resin are situated only in the front, and the backsheets or back layers can be made out of another material, flax or hemp for example.

According to a preferred embodiment, the layer of dry fabric and the layer of fabric pre-impregnated with resin are in contact before the baking. According to a simplified embodiment, the layer of pre-impregnated of resin is sufficient to provide for bonding after baking.

The encapsulation surface plate enables the transmission of its surface condition to the “frontsheet” polymer layer, and its surface its therefore smooth and without roughness and has a pleasant appearance. The layers C1, C2, C3, C5, C6 and C7 are cut out to the same dimension, which is relatively greater in width and in length than that the layer (C4) of photovoltaic cells. The fact that at least the layers (C2, C5) of dry fabric have dimensions greater than those of at least the layer of photovoltaic cells (C4) particularly improves the extraction of gases through the side of the stack during the baking. This inequality of dimensions between the layers requires a trimming operation at the end of the process.

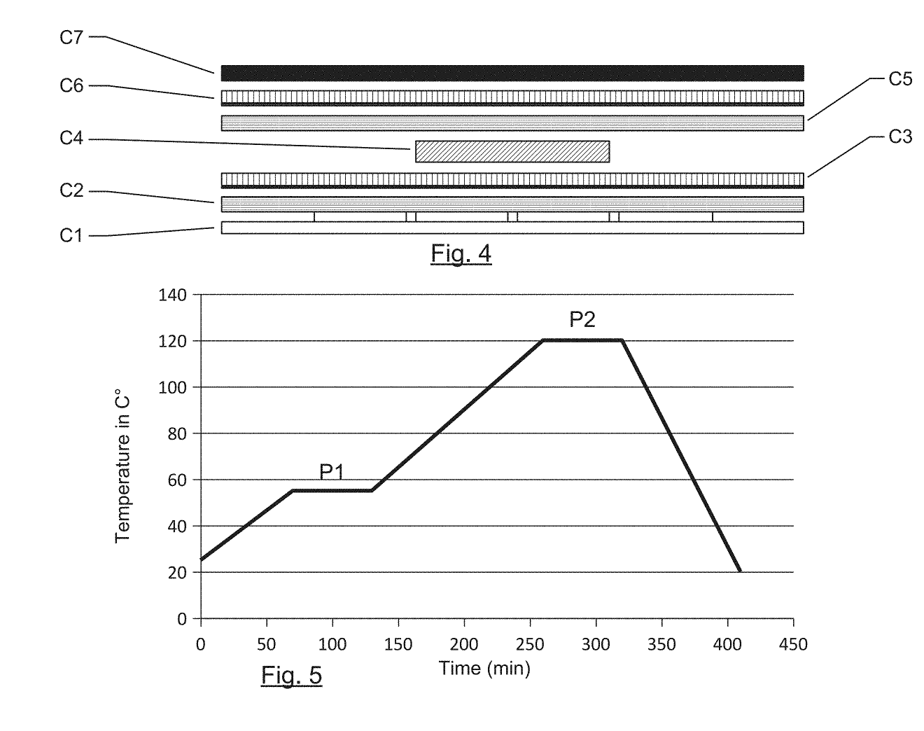

FIG. 4 represents a diagram showing the succession of layers to be made before the baking of the stack. The layers C1 to C7 are superimposed preferably in the precise order listed here above, and constitute the sheet once encapsulated by the epoxy resin. This sheet typically has a thickness of 0.9 mm for a weight of 1600 g/m².

After the step 1.6 for stacking the layers, the operator carries out a step of preparation (step 1.7) for encapsulation in using layers of consumables. The seven layers C1 to C7 are coated firstly with a tear-off fabric, which is itself coated with a separating film. Finally, the entire unit is covered with a air-removal felt element enabling the extraction of pumped-out air. The preparation step 1.7 comprises the cutting out of the three layers of consumables. The preparation step 1.7 terminates with the addition of a vacuum-creating film and the application of a sealant all around this film.

The baking step 1.8 starts with the extraction of air beneath the film so as to create a vacuum to eliminate the air that would be detrimental to the encapsulation and so as to enable the film to exert pressure on all the layers and to place them flat against the encapsulation surface plate. The layers of dry fabric therefore initially enable the removal of the air and secondly the suction of the gases produced by heating of the epoxy resin that impregnates the other fabrics. In this way, during the baking step, almost all the gases are driven out of the stack to the exterior of the stack by a vacuum pump. The heating then comes into play while the vacuum reaches a pressure of 0.9 bars. The removal of the air must last at least 60 minutes before baking.

A temperature regulating device precisely regulates the baking cycle of the different materials forming the stack. The temperature cycle is constituted by two levels. The first level at 55° C. approximately serves to compact and remove the air released during the softening of the resin (lowering of viscosity). The second level, at 120° approximately, is necessary to obtain a rate of progress of the chemical reaction close to 100%.

FIG. 5 represents the variation of temperature as a function of time enabling the optimal baking of the layers according to one example of an embodiment. According to the example illustrated, the baking cycle lasts 400 minutes. Once the cycle is completed, the temperature falls gradually and it is advised to open the doors of the oven slightly for a minimum duration, for example 30 minutes, before handling the encapsulation surface plate and uncovering the raw sheet.

Once the baking is terminated, the operator carries out a finishing step (step 1.9). At the beginning of this step, the operator removes the vacuum-creating film, the air-removal felt element, the separator and the tear-off fabric. The rough photovoltaic panel in its as-molded state appears and its rigidity makes it easy to handle. The operator trims the panel by means of scissors to give the same size for each encapsulated layer. As a variant, this operation can be automated by means of a robot provided with a cutting-out tool. Once the panel has been trimmed, a protective varnish is deposited on the edges of the panel.

At the step 1.10, connectors are placed. Each connector enables a hermetically sealed, solid link between the cells of the panel and the connection cables for connection with the inverter. The connector then takes the form of a small box, preferably bonded to the surface of the panel and filled with an injectable material. The connection is done in a simple way by two copper ribbons emerging from the composite material. Inside the connector, these tabs are connected by braising to the internal contact coming from the cells. In order to provide for perfect hermetic sealing, the connectors are filled with a silicone-coated epoxy resin and the lid is closed. It is possible at this state to carry out a test of electrical continuity by polarizing the sheet inversely on a power supply limited in current.

At the end of the steps of the method, the photovoltaic panel thus made has a lightness (1,600 kg/m²) far greater than that of the panels commercially implemented at the time of filing of the present Application. In addition, such a sheet has increased flexibility. Indeed, the sheet is resistant at a curvature of radius 200 mm, thus enabling it to be installed on curved surfaces and thus enabling it to be rolled for transportation. The sheet thus made also has high efficiency, excellent reliability validated during the certification and low cost of industrial scale application.

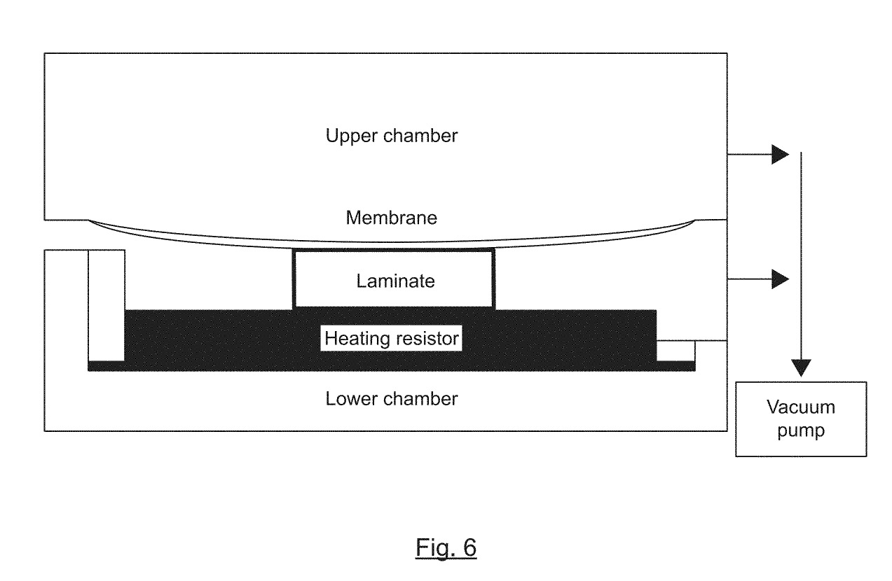

According to one alternative embodiment, the baking is done in an apparatus called a laminator which is illustrated schematically in FIG. 6. This apparatus makes it possible both to heat the layers and keep them under pressure. The laminator therefore has an upper chamber and a lower chamber. The temperature and the pressure of each of these chambers are controlled by the vacuum pump and heating resistors. The stack of the layers of materials constituting the photovoltaic panel, known as a “laminate”, is positioned in the laminator between the two chambers.

The lamination cycle starts with the introduction of the unit constituted by cells and encapsulating materials (composite) into the lower chamber of the laminator where the temperature is kept constant at 120° C. The upper chamber, the lower membrane of which is at this time under pressure of −0.9 bars is almost entirely under vacuum. The lamination is done in two stages. In a first stage, the air within the interior of lower chamber containing the laminate is pumped out, and this is done for 3 minutes. The level of vacuum attained is then −0.9 bars and will be maintained during the lamination and polymerization operations. In a second stage, while the upper chamber is kept under vacuum at −0.9 bars during these first 3 minutes, it will be put under atmospheric pressure for 1 min, and this will be done until the polymerization is complete (1 h at) 120°.

It must be clear to those skilled in the art that the present invention enables embodiments in many other specific forms without departing from the field of application of the invention as claimed. The present embodiments therefore should be considered as illustrations but can be modified in the field defined by the scope of the appended claims.

1. A method for manufacturing a panel of photovoltaic cells comprising:
stacking comprising positioning plurality of layers of different materials to form a stack:
a translucent front layer,
at least two layers of dry fabric made of fiberglass,
at least two layers of fiberglass fabric pre-impregnated with epoxy resin,
a layer of photovoltaic cells,
a back layer,
wherein the translucent front layer and the layer of photovoltaic cells are separated by a layer of the dry fabric made of fiberglass and a layer of the fiberglass fabric pre-impregnated with epoxy resin and
wherein the layer of photovoltaic cells and the back layer are also separated by a second layer of the dry fabric made of fiberglass and a second layer of the fiberglass fabric pre-impregnated with epoxy resin; and
baking the stack of plurality of layers.

2. The method for manufacturing a panel of photovoltaic cells according to claim 1, wherein the stacking comprises stacking the layers in the following order:
the translucent front layer placed on a front of the panel,
the layer of the fiberglass dry fabric,
the layer of fiberglass fabric pre-impregnated with epoxy resin,
the layer of photovoltaic cells,
the second layer of fiberglass dry fabric,
the second layer of fiberglass fabric pre-impregnated with epoxy resin,
the back layer of the panel.

3. The method for manufacturing a panel of photovoltaic cells according to claim 2, wherein the translucent front layer that is in contact with a flat support on which the baking is performed.

4. The method for manufacturing a panel of photovoltaic cells according to claim 1, wherein the baking begins with a preliminary step of placing the stack under vacuum.

5. The method for manufacturing a panel of photovoltaic cells according to claim 4, wherein the preliminary step of placing the stack under vacuum is done by applying a vacuum-creating film on the stack and drawing out air from beneath the film by a vacuum pump.

6. The method for manufacturing a panel of photovoltaic cells according to claim 1, wherein the stacking comprises application of the layers of dry fabric with dimensions greater than that of at least the layer of photovoltaic cells, and a finishing step comprising trimming the panel thus made.

7. The method for manufacturing a panel of photovoltaic cells according to claim 1, wherein the baking comprises successively baking the stack at a first temperature level for a determined duration baking the stack at a second temperature level having a value greater than that of the first level for a second determined duration and then keeping the stack without moving the stack after baking for a third determined duration.

8. The method for manufacturing a panel of photovoltaic cells according to claim 4, wherein the baking of the stack under vacuum is done in a laminator.

9. The method for manufacturing a panel of photovoltaic cells according to claim 1 wherein, prior to the stacking layers, the method comprises making the layer of photovoltaic cells comprising connecting rows of series-connected cells, said rows being connected to one another by field-effect transistors that are encapsulated in the panel at the end of the baking.

10. The method for manufacturing a panel of photovoltaic cells according to claim 9, further comprising setting up connectors electrically connected to electrical bus lines connected to the cells and coming out of the stack, the connectors being capped by silicone-filled packages.

11. The method for manufacturing a panel of photovoltaic cells according to claim 1, wherein the back layer is opaque.

12. A photovoltaic panel comprising at least one stack of layers in the following order:
a translucent front layer placed on a front of the panel,
a first layer of fiberglass dry fabric and a first layer of fiberglass fabric pre-impregnated with epoxy resin,
a layer of photovoltaic cells,
a second layer of fiberglass dry fabric and a second layer of fiberglass fabric pre-impregnated with epoxy resin, and
a back layer of the panel.

13. The photovoltaic panel according to claim 12, wherein the translucent front layer is made of polymers.

14. The photovoltaic panel according to claim 12, wherein the back layer is made of polymers.
